(19) United States
(12) Patent Application Publication
(10) Pub. No.: US 2022/0130840 A1
(43) Pub. Date: Apr. 28, 2022

(54) SEMICONDUCTOR STRUCTURE AND SEMICONDUCTOR STRUCTURE MANUFACTURING METHOD

(71) Applicant: CHANGXIN MEMORY TECHNOLOGIES, INC., Hefei City (CN)

(72) Inventors: Xinru HAN, Hefei City (CN); Ran Li, Hefei City (CN)

(21) Appl. No.: 17/456,081

(22) Filed: Nov. 22, 2021

Related U.S. Application Data
(63) Continuation of application No. PCT/CN2021/112453, filed on Aug. 13, 2021.

(30) Foreign Application Priority Data
Oct. 26, 2020 (CN) 202011155878.4

(51) Int. Cl. H01L 27/108; H01L 29/06

(52) U.S. Cl. CPC H01L 27/10897; H01L 29/0649; H01L 27/10888; H01L 27/10885; H01L 27/10805

(57) ABSTRACT

The present disclosure relates to the field of semiconductor technologies, and provides a semiconductor structure and a semiconductor structure manufacturing method. The semiconductor structure includes a substrate, a bitline, a bitline isolator, a peripheral gate and a gate isolator. A plurality of active regions are formed in the substrate. The bitline is located on the substrate and connected to the active region. The bitline isolator is located on the substrate and covers a sidewall of the bitline. The bitline isolator includes a first air gap. The peripheral gate is located on the substrate. The gate isolator is located on the substrate and covers a sidewall of the peripheral gate. The gate isolator includes a second air gap.

### CROSS-REFERENCE TO RELATED APPLICATIONS

This application is a continuation application of International Patent Application No. PCT/CN2021/112453, which claims priority to Chinese Patent Application No. 202011155878.4, filed with the Chinese Patent Office on Oct. 26, 2020 and entitled “SEMICONDUCTOR STRUCTURE AND SEMICONDUCTOR STRUCTURE MANUFACTURING METHOD.” International Patent Application No. PCT/CN2021/112453 and Chinese Patent Application No. 202011155878.4 are incorporated herein by reference in their entireties.

### TECHNICAL FIELD

The present disclosure relates to the field of semiconductor technologies, and in particular, to a semiconductor structure and a semiconductor structure manufacturing method.

### BACKGROUND

In a semiconductor structure, such as a Dynamic Random Access Memory (DRAM) device, nitride layers are used as sidewalls of a bitline and a peripheral gate, which has limited insulation properties, thereby affecting the performance of the semiconductor structure.

### SUMMARY

The present disclosure provides a semiconductor structure and a semiconductor structure manufacturing method, so as to improve the performance of the semiconductor structure.

According to a first aspect of the present disclosure, a semiconductor structure is provided, including:

a substrate, a plurality of active regions being formed in the substrate;

a bitline, the bitline being located on the substrate and connected to the active region;

a bitline isolator, the bitline isolator being located on the substrate and covering a sidewall of the bitline, the bitline isolator including a first air gap;

a peripheral gate, the peripheral gate being located on the substrate; and

a gate isolator, the gate isolator being located on the substrate and covering a sidewall of the peripheral gate, the gate isolator including a second air gap.

According to a second aspect of the present disclosure, a semiconductor structure manufacturing method is provided, including:

providing a substrate, the substrate including a memory cell region and a peripheral circuit region, a plurality of active regions being formed in the memory cell region;

forming a bitline on the memory cell region, the bitline being connected to the active region;

forming a bitline isolator on the memory cell region, the bitline isolator covering a sidewall of the bitline, the bitline isolator including a first air gap;

forming a peripheral gate on the peripheral circuit region; and

forming a gate isolator on the peripheral circuit region, the gate isolator covering a sidewall of the peripheral gate, the gate isolator including a second air gap.

### BRIEF DESCRIPTION OF DRAWINGS

Various objectives, features and advantages of the present disclosure will become more obvious in consideration of the following detailed description of preferred embodiments of the present disclosure with reference to the accompanying drawings. The accompanying drawings are merely schematic representations of the present disclosure and are not necessarily drawn to scale. The same reference numerals in the accompanying drawings denote the same or similar parts. In the drawings,

FIG. 1 is a schematic flowchart of a semiconductor structure manufacturing method according to an exemplary embodiment;

FIG. 2 is a schematic structural diagram of formation of a first mask layer in a semiconductor structure manufacturing method according to an exemplary embodiment;

FIG. 3 is a schematic structural diagram of formation of a first opening and a second opening in a semiconductor structure manufacturing method according to an exemplary embodiment;

FIG. 4 is a schematic structural diagram of formation of a first isolation material layer in a semiconductor structure manufacturing method according to an exemplary embodiment;

FIG. 5 is a schematic structural diagram of formation of a first isolation layer and a third isolation layer in a semiconductor structure manufacturing method according to an exemplary embodiment;

FIG. 6 is a schematic structural diagram of formation of a first insulation material layer in a semiconductor structure manufacturing method according to an exemplary embodiment;

FIG. 7 is a schematic structural diagram of formation of a first insulation layer and a second insulation layer in a semiconductor structure manufacturing method according to an exemplary embodiment;

FIG. 8 is a schematic structural diagram of formation of a second isolation material layer in a semiconductor structure manufacturing method according to an exemplary embodiment;

FIG. 9 is a schematic structural diagram of formation of a second isolation layer and a fourth isolation layer in a semiconductor structure manufacturing method according to an exemplary embodiment;

FIG. 10 is a schematic structural diagram of formation of a second mask layer in a semiconductor structure manufacturing method according to an exemplary embodiment;

FIG. 11 is a schematic structural diagram of formation of a third mask layer in a semiconductor structure manufacturing method according to an exemplary embodiment;

FIG. 12 is a schematic structural diagram of formation of a bitline contact portion and a peripheral gate contact portion in a semiconductor structure manufacturing method according to an exemplary embodiment;

FIG. 13 is a schematic structural diagram of formation of a metal conductive material layer in a semiconductor structure manufacturing method according to an exemplary embodiment;

FIG. 14 is a schematic structural diagram of formation of a bitline metal portion and a peripheral gate metal portion in a semiconductor structure manufacturing method according to an exemplary embodiment;

FIG. 15 is a schematic structural diagram of formation of a second insulation material layer in a semiconductor structure manufacturing method according to an exemplary embodiment;

FIG. 16 is a schematic structural diagram of formation of a bitline insulation portion and a peripheral gate insulation portion in a semiconductor structure manufacturing method according to an exemplary embodiment;

FIG. 17 is a schematic structural diagram of formation of a first air gap and a second air gap in a semiconductor structure manufacturing method according to an exemplary embodiment;

FIG. 18 is a schematic structural diagram of formation of a fourth mask layer in a semiconductor structure manufacturing method according to an exemplary embodiment;

FIG. 19 is a schematic structural diagram of a semiconductor structure manufacturing method after removal of a fourth mask layer according to an exemplary embodiment;

FIG. 20 is a schematic structural diagram of formation of a sealing layer in a semiconductor structure manufacturing method according to an exemplary embodiment; and

FIG. 21 is a top view of a partial structure of a semiconductor structure according to an exemplary embodiment.

### REFERENCE NUMERALS

10: substrate; 11: active region; 12: memory cell region; 13: peripheral circuit region; 14: dielectric layer; 20: bitline; 21: bitline contact portion; 22: bitline metal portion; 23: bitline insulation portion; 30: bitline isolator; 31: first air gap; 32: first isolation layer; 33: second isolation layer; 40: peripheral gate; 41: peripheral gate contact portion; 42: peripheral gate metal portion; 43: peripheral gate insulation portion; 50: gate isolator; 51: second air gap; 52: third isolation layer; 53: fourth isolation layer; 60: plug;

70: first insulator; 71: first opening; 72: second opening; 73: first insulation layer; 74: second insulation layer; 75: first semiconductor layer; 76: first mask layer; 77: first isolation material layer; 78: first insulation material layer; 79: second isolation material layer; 80: second semiconductor material layer; 81: second mask layer; 82: third mask layer; 83: metal conductive material layer; 84: second insulation material layer; 85: oxide layer; 86: nitride layer; 87: fourth mask layer; 90: sealing layer.

### DESCRIPTION OF EMBODIMENTS

Exemplary embodiments embodying the features and advantages of the present disclosure will be described in detail in the following description. It should be understood that the present disclosure can have various modifications in the various embodiments without departing from the scope of the present disclosure, and the description and the drawings are only intended for illustration but not to limit the present disclosure.

In the following description of the various exemplary embodiments of the present disclosure, with reference to the drawings, the drawings form a part of the present disclosure and various exemplary structures, systems, and steps that can implement various aspects of the present disclosure are shown by way of examples. It should be understood that the specific solutions of the components, structures, exemplary devices, systems, and steps can be used and structural and functional modifications can be made without departing from the scope of the present disclosure. Moreover, although the terms “above”, “between”, “inside” and the like may be used in this specification to describe various example features and elements of the present disclosure, these terms are used herein as a matter of convenience, e.g., based on the example orientations shown in the drawings. No content in this specification should be construed as requiring a specific three-dimensional orientation of structures in order to fall within the scope of the present disclosure.

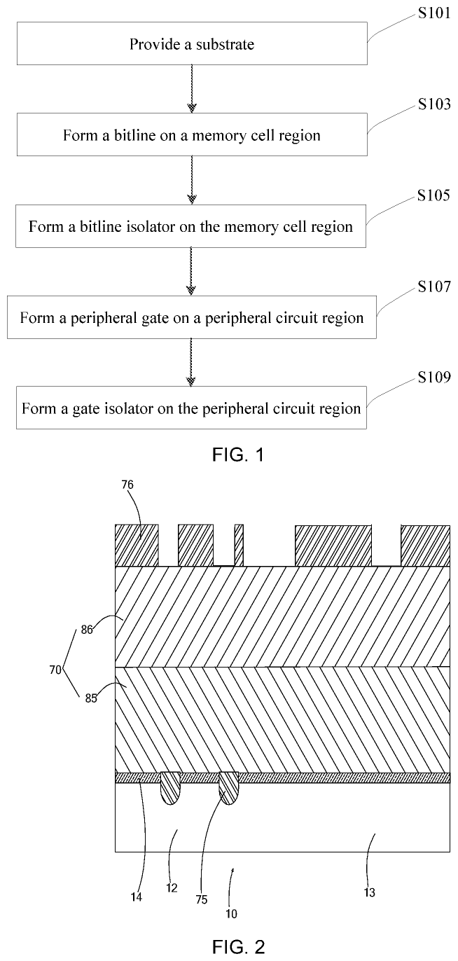

One embodiment of the present disclosure provides a semiconductor structure manufacturing method. Referring to FIG. 1, the semiconductor structure manufacturing method includes the following steps.

In S101, a substrate 10 is provided, the substrate 10 including a memory cell region 12 and a peripheral circuit region 13, a plurality of active regions 11 being formed in the memory cell region 12.

In S103, a bitline 20 is formed on the memory cell region 12, the bitline 20 being connected to the active region 11.

In S105, a bitline isolator 30 is formed on the memory cell region 12, the bitline isolator 30 covering a sidewall of the bitline 20, the bitline isolator 30 including a first air gap 31.

In S107, a peripheral gate 40 is formed on the peripheral circuit region 13.

In S109, a gate isolator 50 is formed on the peripheral circuit region 13, the gate isolator 50 covering a sidewall of the peripheral gate 40, the gate isolator 50 including a second air gap 51.

In the semiconductor structure according to one embodiment of the present disclosure, the bitline 20 and the peripheral gate 40 are formed on the substrate 10, the bitline isolator 30 covering a sidewall of the bitline 20 includes the first air gap 31, and the gate isolator 50 covering a sidewall of the peripheral gate 40 includes the second air gap 51; that is, the first air gap 31 and the second air gap 51 serve as sidewall insulation structures of the bitline 20 and the peripheral gate 40 respectively, so that sidewall insulation properties can be improved, so as to improve the performance of the semiconductor structure.

It is to be noted that, a capacitor contact line may be arranged adjacent to the bitline 20, and the arrangement of the first air gap 31 and the second air gap 51 can reduce a coupling effect between the bitline 20 and the capacitor contact line and reduce parasitic capacitance there between, so as to obtain better electrical properties.

In some embodiments, the first air gap 31 and the second air gap 51 are synchronously formed by a same process, which can reduce a semiconductor forming process.

It is to be noted that, the synchronous formation herein does not refer in particular to simultaneous formation in a same time period, and there is no time difference between the two, provided that the formation of the first air gap 31 and the second air gap 51 is not interrupted by any other intermediate process step. It is not ruled out that the formation of the first air gap 31 and the second air gap 51 has front and back states, but the process of forming the first air gap 31 and the second air gap 51 is a continuous process. Certainly, if the process permits, the first air gap 31 and the second air gap 51 may be simultaneously formed in a same time period.

In some embodiments, the step of forming the first air gap 31 and the second air gap 51 includes: forming a first insulator 70 on the substrate 10; forming a first opening 71 and a second opening 72 on the first insulator 70, a bottom of the first opening 71 being located in the memory cell region 12, a bottom of the second opening 72 being located in the peripheral circuit region 13; forming a first isolation layer 32 and a third isolation layer 52 on sidewalls of the first opening 71 and the second opening 72 respectively; forming a first insulation layer 73 and a second insulation layer 74 on sidewalls of the first isolation layer 32 and the third isolation layer 52 respectively; forming a second isolation layer 33 and a fourth isolation layer 53 on sidewalls of the first insulation layer 73 and the second insulation layer 74 respectively; forming the bitline 20 and the peripheral gate 40 in the second isolation layer 33 and the fourth isolation layer 53 respectively; and removing the first insulation layer 73 and the second insulation layer 74, an air gap between the first isolation layer 32 and the second isolation layer 33 serving as the first air gap 31, an air gap between the third isolation layer 52 and the fourth isolation layer 53 serving as the second air gap 51, wherein the first isolation layer 32, the second isolation layer 33 and the first air gap 31 serve as the bitline isolator 30, and the third isolation layer 52, the fourth isolation layer 53 and the second air gap 51 serve as the gate isolator 50.

The bitline isolator 30 includes the first isolation layer 32, the second isolation layer 33 and the first air gap 31. The gate isolator 50 includes the third isolation layer 52, the fourth isolation layer 53 and the second air gap 51. Firstly, the first insulation layer 73 is formed between the first isolation layer 32 and the second isolation layer 33, and the second insulation layer 74 is formed between the third isolation layer 52 and the fourth isolation layer 53. Then, the first insulation layer 73 and the second insulation layer 74 are removed by a process such as etching, so as to form the first air gap 31 and the second air gap 51. In this embodiment, the first insulation layer 73 and the second insulation layer 74 are removed by wet etching. The removal processes of the first insulation layer 73 and the second insulation layer 74 are in a same step, with no other steps there between.

In some embodiments, a first semiconductor layer 75 is formed in the substrate 10, and the step of forming the first opening 71 and the second opening 72 includes: forming a first mask layer 76 on the first insulator 70, the first mask layer 76 exposing a first region corresponding to the first opening 71 and a second region corresponding to the second opening 72; and forming the first opening 71 in the first region and the second opening 72 in the second region by an etching process, wherein the bottom of the first opening 71 is located in the substrate 10 so that a part of the first semiconductor layer 75 is etched, a remaining part of the first semiconductor layer 75 serves as a plug 60 connecting the active region 11 and the bitline 20, and the bottom of the second opening 72 is located on an upper surface of the substrate 10.

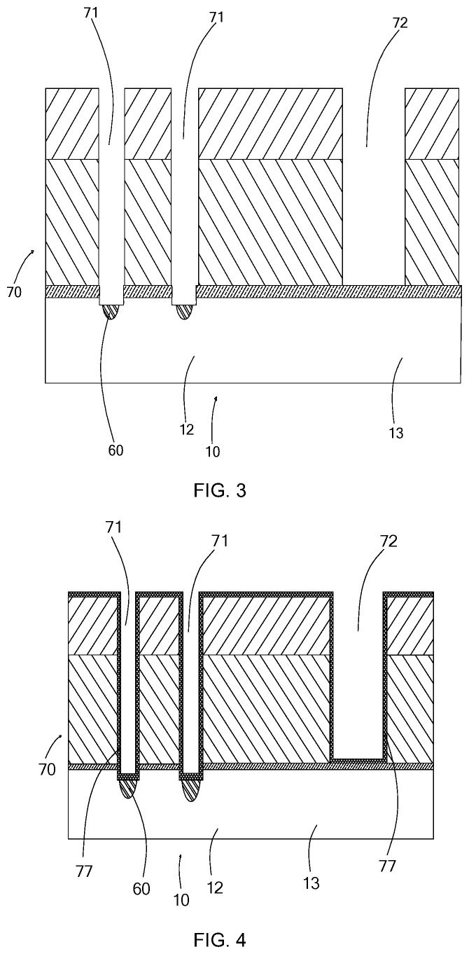

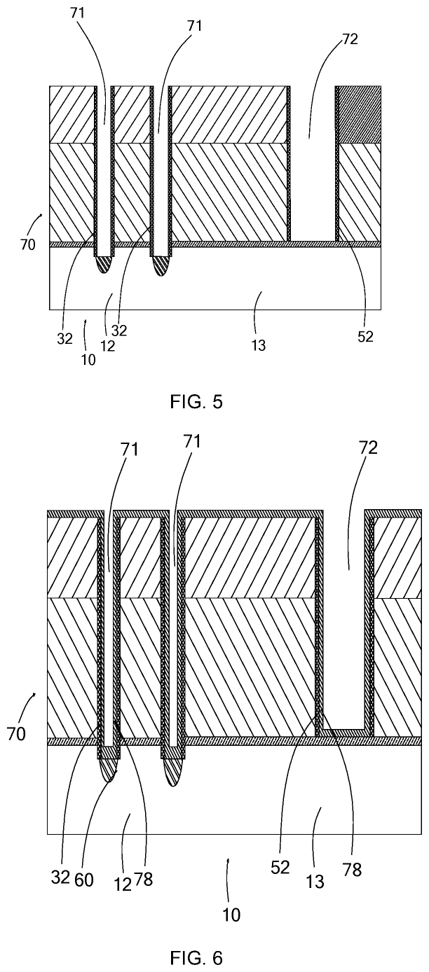

Referring to FIG. 2, the substrate 10 includes the memory cell region 12 and the peripheral circuit region 13. The first semiconductor layer 75 is formed in the memory cell region 12. A top of the first semiconductor layer 75 is flush with a top of the substrate 10. The top of the first semiconductor layer 75 is configured to connect the active region 11. The substrate 10 includes a dielectric layer 14. An oxide layer 85 is formed on the dielectric layer 14. A nitride layer 86 is formed on the oxide layer 85. The oxide layer 85 and the nitride layer 86 serve as the first insulator 70. Then, the first mask layer 76 is formed on the first insulator 70. Thus, the structure shown in FIG. 3 is formed by etching the first insulator 70 exposed by the first mask layer 76; that is, the first opening 71 and the second opening 72 are formed.

It is to be noted that, a channel isolation layer is formed on the substrate 10, so as to obtain a plurality of active regions 11 by isolation. The channel isolation layer may be formed by a Shallow Trench Isolation (STI) process. The channel isolation layer may include silicon dioxide (SiO₂). The dielectric layer 14 may be made of silicon dioxide (SiO₂) or a High-K material.

The formation process of the first semiconductor layer 75 is not limited herein, which may be a process in the related art.

Specifically, the oxide layer 85 may be made of a material such as silicon dioxide (SiO₂) or silicon oxycarbide (SiOC). The nitride layer 86 may be made of a material such as silicon nitride (SiN) or silicon carbonitride (SiCN). The first mask layer 76 is a photoresist.

The first semiconductor layer 75 may be made of a silicon-containing material. The first semiconductor layer 75 may be formed by any appropriate material, which includes, for example, at least one of silicon, monocrystalline silicon, polysilicon, amorphous silicon, silicon germanium, monocrystalline silicon germanium, polysilicon silicon germanium, and carbon-doped silicon.

It is to be noted that, the oxide layer 85, the nitride layer 86 and the first mask layer 76 may be formed by a Physical Vapor Deposition (PVD) process, a Chemical Vapor Deposition (CVD) process, an Atomic Layer Deposition (ALD) process or the like.

In some embodiments, a first isolation material layer 77 is formed on the first insulator 70. The first isolation layer 32 and the third isolation layer 52 are formed by etching a part of the first isolation material layer 77; that is, the first isolation layer 32 and the third isolation layer 52 are formed by a same material and a same process in a same procedure.

Specifically, the step of forming the first isolation layer 32 and the third isolation layer 52 includes: forming the first isolation material layer 77 on the first insulator 70, the first isolation material layer 77 covering a sidewall and a bottom wall of the first opening 71 and a sidewall and a bottom wall of the second opening 72; and etching part of the first isolation material layer 77 in the first opening 71 and the second opening 72, and exposing an upper surface of the plug 60 and an upper surface of the substrate 10 respectively, so that the remaining first isolation material layer 77 serves as the first isolation layer 32 and the third isolation layer 52 respectively.

Specifically, on the basis of FIG. 3, the first isolation material layer 77 is formed on the nitride layer 86, as shown in FIG. 4. The first isolation material layer 77 covers an upper surface of the nitride layer 86, the sidewall and the bottom wall of the first opening 71 and the sidewall and the bottom wall of the second opening 72, as shown in FIG. 4. The first isolation material layer 77 on the upper surface of the nitride layer 86 and the first isolation material layer 77 on the bottom wall of the first opening 71 and the bottom wall of the second opening 72 are etched, so that the first isolation material layer 77 covers only the sidewall of the first opening 71 and the sidewall of the second opening 72, as shown in FIG. 5. The first isolation material layer 77 on the bottom wall of the first opening 71 is etched to expose the plug 60, and the first isolation material layer 77 on the bottom wall of the second opening 72 is etched to expose the substrate 10.

It is to be noted that, part of the nitride layer 86 may also be etched away when the first isolation material layer 77 on the upper surface of the nitride layer 86 is etched. Alternatively, the first isolation material layer 77 on the upper surface of the nitride layer 86 may not be etched; that is, only the first isolation material layer 77 on the bottom wall of the first opening 71 and the bottom wall of the second opening 72 is etched.

In some embodiments, a first insulation material layer 78 is formed on the first insulator 70. The first insulation layer 73 and the second insulation layer 74 are formed by etching a part of the first insulation material layer 78; that is, the first insulation layer 73 and the second insulation layer 74 are formed by a same material and a same process in a same procedure.

Specifically, the step of forming the first insulation layer 73 and the second insulation layer 74 includes: forming the first insulation material layer 78 on the first insulator 70, the first insulation material layer 78 covering a sidewall and a bottom wall of the first opening 71 and a sidewall and a bottom wall of the second opening 72; and etching the first insulation material layer 78 in the first opening 71 and the second opening 72, and exposing an upper surface of the plug 60 and an upper surface of the substrate 10, so that the remaining first insulation material layer 78 serves as the first insulation layer 73 and the second insulation layer 74 respectively.

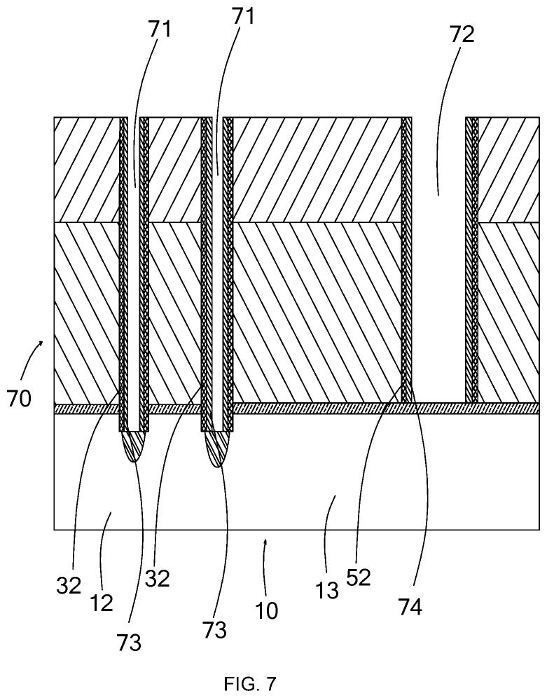

On the basis of FIG. 5, the first insulation material layer 78 is formed on the nitride layer 86. As shown in FIG. 6, the first insulation material layer 78 covers an upper surface of the nitride layer 86, a sidewall of the first isolation layer 32, a bottom wall of the first opening 71, a sidewall of the third isolation layer 52 and a bottom wall of the second opening 72. The first insulation material layer 78 on the upper surface of the nitride layer 86 and the first insulation material layer 78 on the bottom wall of the first opening 71 and the bottom wall of the second opening 72 are etched, so that the first insulation material layer 78 covers only the sidewall of the first isolation layer 32 and the sidewall of the third isolation layer 52, as shown in FIG. 7.

It is to be noted that, part of the nitride layer 86 may also be etched away when the first insulation material layer 78 on the upper surface of the nitride layer 86 is etched. Alternatively, the first insulation material layer 78 on the upper surface of the nitride layer 86 may not be etched; that is, only the first insulation material layer 78 on the bottom wall of the first opening 71 and the bottom wall of the second opening 72 is etched.

In some embodiments, a second isolation material layer 79 is formed on the first insulator 70. The second isolation layer 33 and the fourth isolation layer 53 are formed by etching a part of the second isolation material layer 79; that is, the second isolation layer 33 and the fourth isolation layer 53 are formed by a same material and a same process in a same procedure.

Specifically, the step of forming the second isolation layer 33 and the fourth isolation layer 53 includes: forming the second isolation material layer 79 on the first insulator 70, the second isolation material layer 79 covering a sidewall and a bottom wall of the first opening 71 and a sidewall and a bottom wall of the second opening 72; and etching the second isolation material layer 79 in the first opening 71 and the second opening 72, and exposing an upper surface of the plug 60 and an upper surface of the substrate 10, so that the remaining second isolation material layer 79 serves as the second isolation layer 33 and the fourth isolation layer 53 respectively.

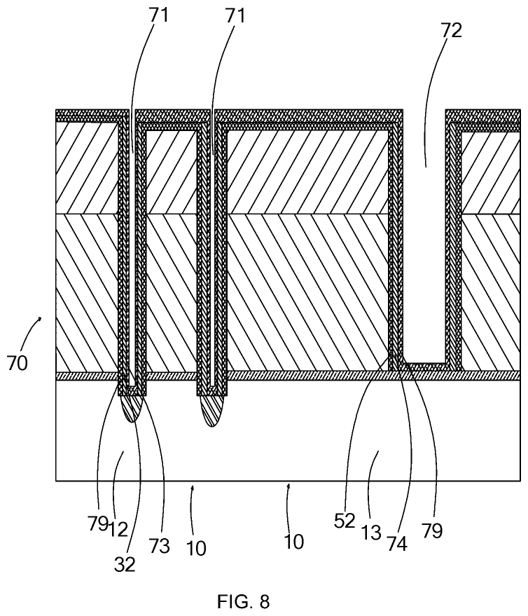

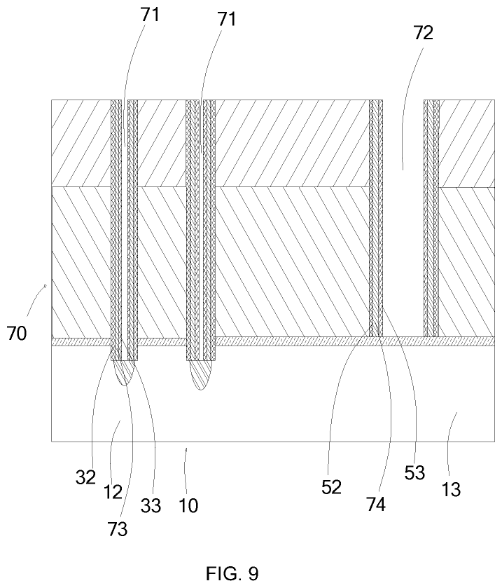

On the basis of FIG. 7, the second isolation material layer 79 is formed on the nitride layer 86. As shown in FIG. 8, the second isolation material layer 79 covers an upper surface of the nitride layer 86, a sidewall of the first insulation layer 73, a bottom wall of the first opening 71, a sidewall of the second insulation layer 74 and a bottom wall of the second opening 72. The second isolation material layer 79 on the upper surface of the nitride layer 86 and the second isolation material layer 79 on the bottom wall of the first opening 71 and the bottom wall of the second opening 72 are etched, so that the second isolation material layer 79 covers only the sidewall of the first insulation layer 73 and the sidewall of the second insulation layer 74, as shown in FIG. 9.

It is to be noted that, part of the nitride layer 86 may also be etched away when the second isolation material layer 79 on the upper surface of the nitride layer 86 is etched. Alternatively, the second isolation material layer 79 on the upper surface of the nitride layer 86 may not be etched; that is, only the second isolation material layer 79 on the bottom wall of the first opening 71 and the bottom wall of the second opening 72 is etched.

It is to be noted that the first isolation material layer 77, the first insulation material layer 78 and the second isolation material layer 79 may be formed by a physical vapor deposition process, a chemical vapor deposition process, an atomic layer deposition process or the like. The first isolation material layer 77 and the second isolation material layer 79 may be made of a same material, which may be made of, for example, silicon nitride (SiN) or silicon carbonitride (SiCN). The first insulation material layer 78 may be made of a material such as silicon dioxide (SiO₂) or silicon oxycarbide (SiOC).

In some embodiments, the first insulator 70 includes an oxide layer 85 and a nitride layer 86, the oxide layer 85 is formed on the substrate 10, the nitride layer 86 is formed on the oxide layer 85, and the bitline 20 and the peripheral gate 40 are formed after all material layers on an upper surface of the oxide layer 85 are removed, wherein the oxide layer 85, the first insulation layer 73 and the second insulation layer 74 are identical material layers to be simultaneously removed by etching.

Specifically, the nitride layer 86 serves as an isolation layer, and prior to the removal of the oxide layer 85, the first insulation layer 73 and the second insulation layer 74, the nitride layer 86 is required to be removed. For example, the nitride layer 86 is removed by a material etching process. In this case, a structural layer embedded in the nitride layer 86 has also been correspondingly removed, so that only a structural layer embedded in the oxide layer 85 is retained. Then, the oxide layer 85, the first insulation layer 73 and the second insulation layer 74 are removed by wet etching, so as to form the first air gap 31 and the second air gap 51; that is, manufacturing efficiency is improved, and a formation process is reduced.

In some embodiments, the step of forming the bitline 20 and the peripheral gate 40 includes: forming a bitline contact portion 21 and a peripheral gate contact portion 41 in the first opening 71 and the second opening 72 respectively; forming a bitline metal portion 22 and a peripheral gate metal portion 42 on the bitline contact portion 21 and the peripheral gate contact portion 41 respectively; and forming a bitline insulation portion 23 and a peripheral gate insulation portion 43 on the bitline metal portion 22 and the peripheral gate metal portion 42 respectively, wherein the bitline contact portion 21, the bitline metal portion 22 and the bitline insulation portion 23 serve as the bitline 20, and the peripheral gate contact portion 41, the peripheral gate metal portion 42 and the peripheral gate insulation portion 43 serve as the peripheral gate 40.

Specifically, the bitline 20 includes the bitline contact portion 21, the bitline metal portion 22 and the bitline insulation portion 23, the bitline contact portion 21 is connected to the plug 60, the bitline metal portion 22 is located on the bitline contact portion 21, and the bitline insulation portion 23 is located on the bitline metal portion 22.

The bitline contact portion 21 may be made of a silicon-containing material. The bitline contact portion 21 may include polysilicon, doped polysilicon, epitaxial silicon or doped epitaxial silicon. In this embodiment, the bitline contact portion 21 may be made of polysilicon.

The bitline metal portion 22 may include at least one of tungsten nitride (WN), molybdenum nitride (MoN), titanium nitride (TIN), tantalum nitride (TaN), titanium silicon nitride (TiSiN), tantalum silicon nitride (TaSiN) and tungsten (W). In this embodiment, the bitline metal portion 22 may be made of titanium nitride and tungsten.

The bitline insulation portion 23 may be formed of materials including silicon oxide, silicon nitride, or a combination thereof. In this embodiment, the bitline insulation portion 23 may be made of silicon nitride.

Correspondingly, the peripheral gate 40 includes the peripheral gate contact portion 41, the peripheral gate metal portion 42 and the peripheral gate insulation portion 43, the peripheral gate contact portion 41 is located on the substrate 10, the peripheral gate metal portion 42 is located on the peripheral gate contact portion 41, and the peripheral gate insulation portion 43 is located on the peripheral gate metal portion 42.

The peripheral gate contact portion 41 may be made of a silicon-containing material. The peripheral gate contact portion 41 may include polysilicon, doped polysilicon, epitaxial silicon or doped epitaxial silicon. In this embodiment, the peripheral gate contact portion 41 may be made of polysilicon.

The peripheral gate metal portion 42 may include at least one of tungsten nitride (WN), molybdenum nitride (MoN), titanium nitride (TiN), tantalum nitride (TaN), titanium silicon nitride (TiSiN), tantalum silicon nitride (TaSiN) and tungsten (W). In this embodiment, the peripheral gate metal portion 42 may be made of titanium nitride and tungsten.

The peripheral gate insulation portion 43 may be formed of materials including silicon oxide, silicon nitride, or a combination thereof. In this embodiment, the peripheral gate insulation portion 43 may be made of silicon nitride.

In some embodiments, a second semiconductor material layer 80 is formed on the first insulator 70, and the bitline contact portion 21 and the peripheral gate contact portion 41 are formed by etching a part of the second semiconductor material layer 80. That is, the bitline contact portion 21 and the peripheral gate contact portion 41 are formed by a same material, so as to reduce a technical process.

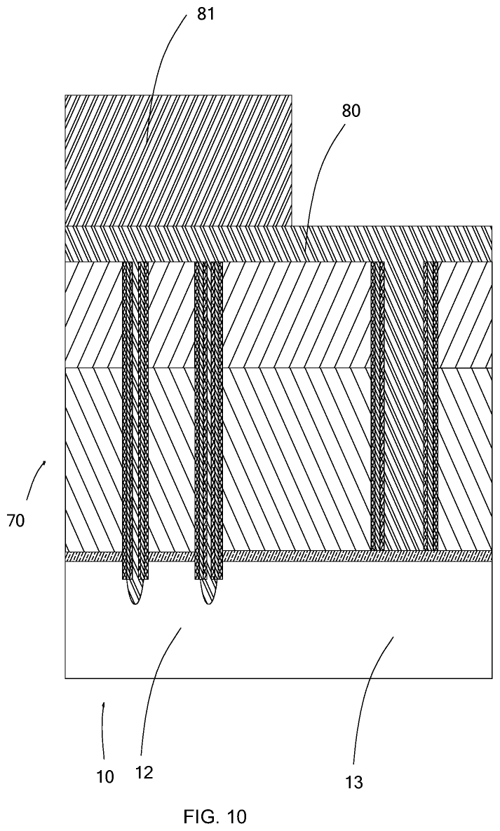

Specifically, on the basis of FIG. 9, the second semiconductor material layer 80 is formed on the first insulator 70, the first opening 71 and the second opening 72 are filled with the second semiconductor material layer 80, a second mask layer 81 is formed on the second semiconductor material layer 80, and the second mask layer 81 covers a region where the memory cell region 12 is located and exposes a region where the peripheral circuit region 13 is located, as shown in FIG. 10.

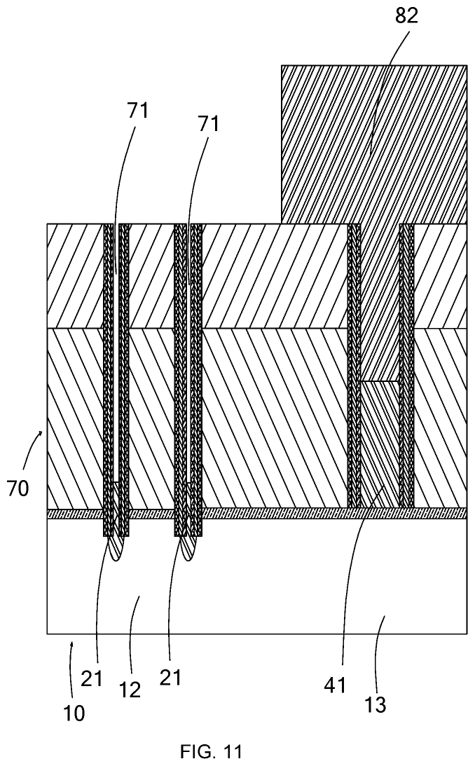

Part of the second semiconductor material layer 80 corresponding to the peripheral circuit region 13 is etched; that is, the entire second semiconductor material layer 80 on the upper surface of the first insulator 70 and part of the second semiconductor material layer 80 in the second opening 72 corresponding to the peripheral circuit region 13 are removed. Part of the second semiconductor material layer 80 remaining in the second opening 72 serves as the peripheral gate contact portion 41, as shown in FIG. 11. Then, a third mask layer 82 is formed on the peripheral circuit region 13. The third mask layer 82 exposes the region where the memory cell region 12 is located.

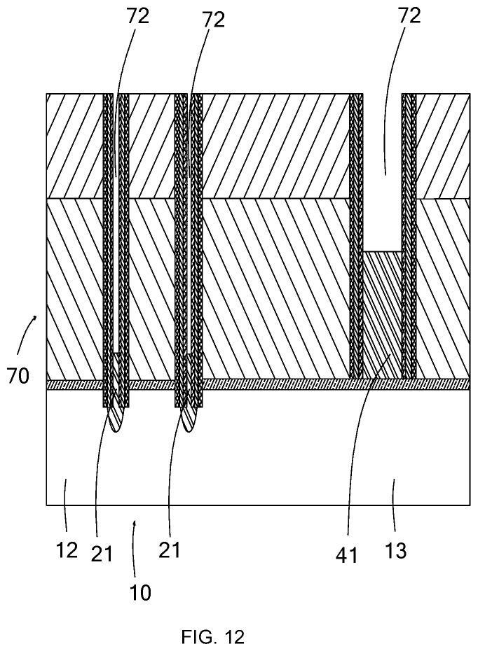

Part of the second semiconductor material layer 80 corresponding to the memory cell region 12 is etched; that is, the entire second semiconductor material layer 80 on the upper surface of the first insulator 70 and part of the second semiconductor material layer 80 in the first opening 71 corresponding to the memory cell region 12 are removed. Part of the second semiconductor material layer 80 remaining in the first opening 71 serves as the bitline contact portion 21. A top end of the bitline contact portion 21 is lower than a top end of the peripheral gate contact portion 41, as shown in FIG. 12.

It is to be noted that, the bitline contact portion 21 may also be formed first, and then the peripheral gate contact portion 41 is formed. A specific formation process is similar to the above method. That is, firstly, the peripheral circuit region 13 is covered with a mask layer, to form the bitline contact portion 21; then, the memory cell region 12 is covered with the mask layer, to form the peripheral gate contact portion 41, which is not described in detail herein.

In some embodiments, a metal conductive material layer 83 is formed on the first insulator 70, and the bitline metal portion 22 and the peripheral gate metal portion 42 are formed by etching a part of the metal conductive material layer 83. That is, the bitline metal portion 22 and the peripheral gate metal portion 42 may be formed by a same material and a same process in a same procedure.

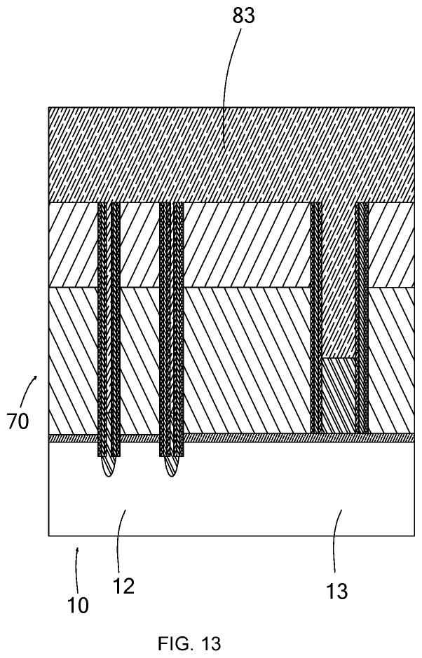

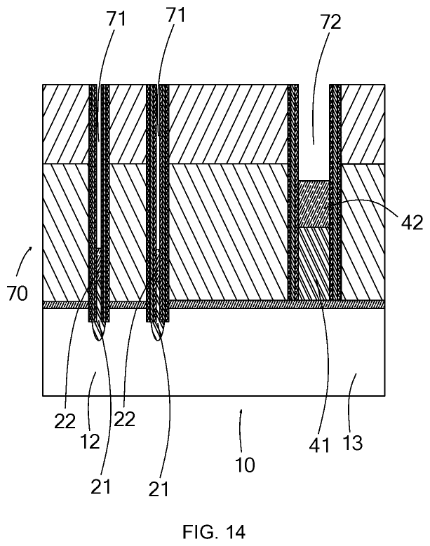

Specifically, on the basis of FIG. 12, the metal conductive material layer 83 is formed on the first insulator 70, and the first opening 71 and the second opening 72 are filled with the metal conductive material layer 83, as shown in FIG. 13.

Part of the metal conductive material layer 83 is etched; that is, the entire metal conductive material layer 83 on the upper surface of the first insulator 70 and part of the metal conductive material layer 83 in the first opening 71 and the second opening 72 are removed. The remaining metal conductive material layer 83 serves as the bitline metal portion 22 and the peripheral gate metal portion 42 respectively, as shown in FIG. 14.

In some embodiments, a second insulation material layer 84 is formed on the first insulator 70, and the bitline insulation portion 23 and the peripheral gate insulation portion 43 are formed by etching a part of the second insulation material layer 84. That is, the bitline insulation portion 23 and the peripheral gate insulation portion 43 may be formed by a same material and a same process in a same procedure.

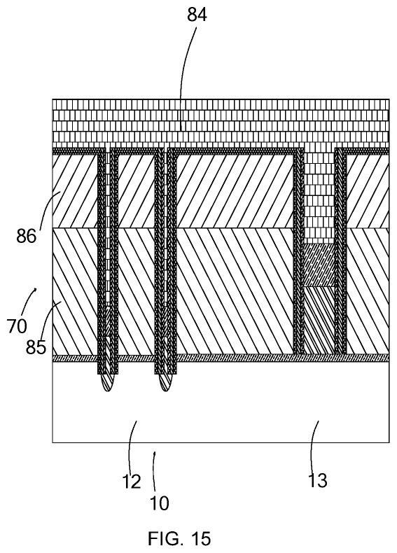

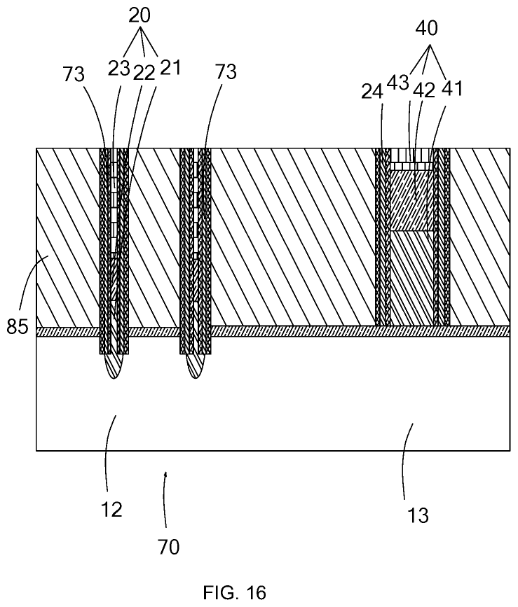

Specifically, on the basis of FIG. 14, the second insulation material layer 84 is formed on the first insulator 70, and the first opening 71 and the second opening 72 are filled with the second insulation material layer 84, as shown in FIG. 15. A region corresponding to the upper surface of the oxide layer 85 is etched to expose the oxide layer 85; that is, the nitride layer 86 and the second insulation material layer 84 on the upper surface of the oxide layer 85 are removed, and a structural layer located in the nitride layer 86 is also removed, as shown in FIG. 16. The second insulation material layer 84 remaining in the first opening 71 and the second opening 72 serves as the bitline insulation portion 23 and the peripheral gate insulation portion 43 respectively.

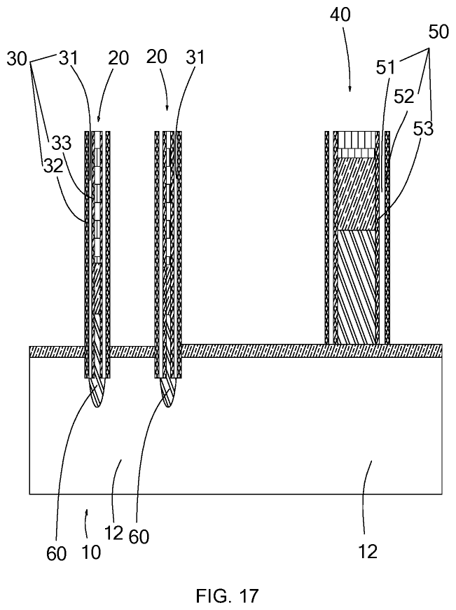

On the basis of FIG. 16, the oxide layer 85, the first insulation layer 73 and the second insulation layer 74 are simultaneously removed by etching, as shown in FIG. 17.

It is to be noted that the second semiconductor material layer 80, the metal conductive material layer 83 and the second insulation material layer 84 may be formed by a physical vapor deposition process, a chemical vapor deposition process, an atomic layer deposition process or the like.

In some embodiments, the semiconductor structure manufacturing method further includes: forming a fourth mask layer 87 on the memory cell region 12, the fourth mask layer 87 exposing the peripheral circuit region 13; and performing ion implantation into the peripheral circuit region 13, so as to form an ion implantation region in the peripheral circuit region 13, that is, form an active region of the peripheral circuit region 13.

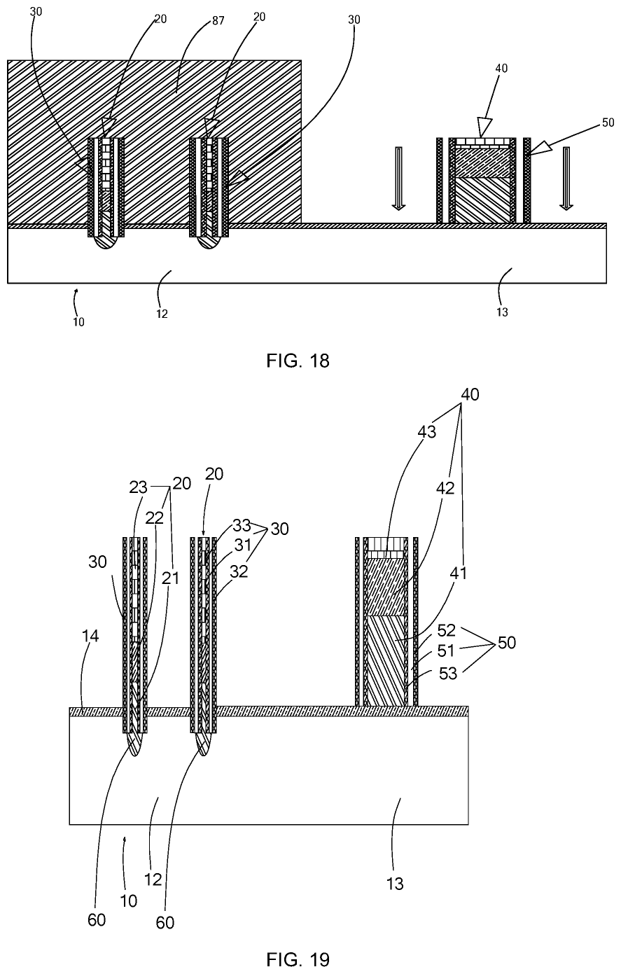

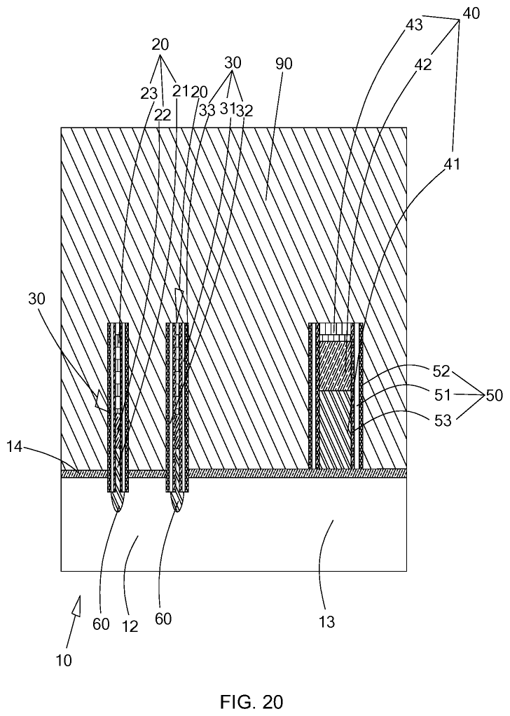

Specifically, on the basis of FIG. 17, the fourth mask layer 87 is formed on the memory cell region 12, as shown in FIG. 18. The fourth mask layer 87 is removed after ion implantation is completed in the peripheral circuit region 13, so as to form a structure shown in FIG. 19.

In some embodiments, the semiconductor structure manufacturing method further includes: forming a sealing layer 90 on the first air gap 31 and the second air gap 51, so as to seal openings of the first air gap 31 and the second air gap 51.

Specifically, on the basis of FIG. 19, the sealing layer 90 is formed on the substrate 10 to embed the bitline 20, the bitline isolator 30, the peripheral gate 40 and the gate isolator 50 into the sealing layer 90, as shown in FIG. 20.

It is to be noted that, the sealing layer 90 may be an oxide layer. The sealing layer 90 may be made of a material such as silicon dioxide (SiO₂ or silicon oxycarbide (SiOC). The sealing layer 90 may be formed by a physical vapor deposition process, a chemical vapor deposition process, an atomic layer deposition process or the like.

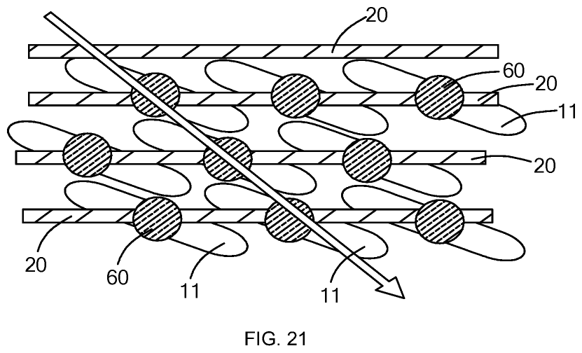

One embodiment of the present disclosure further provides a semiconductor structure. Referring to FIG. 20 and FIG. 21, the semiconductor structure includes: a substrate 10, a plurality of active regions 11 being formed in the substrate 10; a bitline 20, the bitline 20 being located on the substrate 10 and connected to the active region 11; a bitline isolator 30, the bitline isolator 30 being located on the substrate 10 and covering a sidewall of the bitline 20, the bitline isolator 30 including a first air gap 31; a peripheral gate 40, the peripheral gate 40 being located on the substrate 10; and a gate isolator 50, the gate isolator 50 being located on the substrate 10 and covering a sidewall of the peripheral gate 40, the gate isolator 50 including a second air gap 51.

In the semiconductor structure according to one embodiment of the present disclosure, the bitline 20 and the peripheral gate 40 are formed on the substrate 10, the bitline isolator 30 covering a sidewall of the bitline 20 includes the first air gap 31, and the gate isolator 50 covering a sidewall of the peripheral gate 40 includes the second air gap 51; that is, the first air gap 31 and the second air gap 51 serve as sidewall insulation structures of the bitline 20 and the peripheral gate 40 respectively, so that sidewall insulation properties can be improved, so as to improve the performance of the semiconductor structure.

In some embodiments, the substrate 10 may be a semiconductor substrate. The semiconductor substrate may be made of a silicon-containing material. The semiconductor substrate may be formed by any appropriate material, which includes, for example, at least one of silicon, monocrystalline silicon, polysilicon, amorphous silicon, silicon germanium, monocrystalline silicon germanium, polysilicon silicon germanium, and carbon-doped silicon.

Specifically, referring to FIG. 20, the substrate 10 includes a memory cell region 12 and a peripheral circuit region 13. The bitline 20 and the bitline isolator 30 are located in the memory cell region 12. The peripheral gate 40 and the gate isolator 50 are located in the peripheral circuit region 13. A channel isolation layer is formed on the substrate 10, so as to obtain a plurality of active regions 11 by isolation. The channel isolation layer may be formed by a Shallow Trench Isolation (STI) process. The channel isolation layer may include silicon dioxide (SiO₂). A top of the substrate 10 includes a dielectric layer 14. The dielectric layer 14 may be made of silicon dioxide (SiO₂) or a High-K material.

In some embodiments, a plurality of bitlines 20 are provided. The plurality of bitlines 20 are spaced apart.

In some embodiments, the first air gap 31 and the second air gap 51 are synchronously formed, so as to improve manufacturing efficiency of the semiconductor structure.

In some embodiments, as shown in FIG. 20, the bitline isolator 30 further includes: a first isolation layer 32, the first isolation layer 32 being located on the substrate 10; and a second isolation layer 33, the second isolation layer 33 being located on the substrate 10 and covering the sidewall of the bitline 20, wherein the first isolation layer 32 is spaced apart from the second isolation layer 33, to form the first air gap 31 between the first isolation layer 32 and the second isolation layer 33; that is, the bitline isolator 30 forms an insulation structure of an isolation layer-an air layer-an isolation layer, so as to improve an insulation effect.

It is to be noted that, a height of the first air gap 31, a height of the first isolation layer 32 and a height of the second isolation layer 33 are all equal.

In some embodiments, the first isolation layer 32 and the second isolation layer 33 may be identical material layers.

In some embodiments, the first isolation layer 32 and the second isolation layer 33 may be different material layers.

In some embodiments, a bottom of the bitline 20 is located in the substrate 10, which may not only form a bottom support and improve stability of the bottom of the bitline 20, but also facilitate a connection between the bitline 20 and the active region 11.

In some embodiments, a bottom of the peripheral gate 40 is located on an upper surface of the substrate 10.

In some embodiments, as shown in FIG. 20, the semiconductor structure further includes: a plug 60. The plug 60 is located in the substrate 10. The bitline 20 is connected to the active region 11 through the plug 60. A plurality of plugs 60 may be provided. The plurality of plugs 60 are arranged corresponding to the plurality of active regions 11, so that two ends of the plug 60 are connected to the active region 11 and the bitline 20 respectively.

In some embodiments, a thickness of the bitline 20 in a first direction is less than a thickness of the plug 60 in the first direction, so that the bitline isolator 30 covers a top end of the plug 60. The first direction is parallel to the substrate 10. The bitline 20 is connected to the middle of the top end of the plug 60, so that the bitline isolator 30 covers a part of the top end of the plug 60.

In some embodiments, a total thickness of the bitline 20 and the bitline isolator 30 in the first direction is greater than the thickness of the plug 60 in the first direction.

In some embodiments, the first air gap 31 may be arranged opposite to the plug 60. Alternatively, the first air gap 31 is misaligned with the plug 60; that is, the second isolation layer 33 covers an empty part of the top end of the plug 60 in the first direction.

It is to be noted that, widths of the first air gap 31 and the second air gap 51 may be equal or unequal, which is not limited herein.

In some embodiments, the gate isolator 50 further includes: a third isolation layer 52, the third isolation layer 52 being located on the substrate 10; and a fourth isolation layer 53, the fourth isolation layer 53 being located on the substrate 10 and covering the sidewall of the peripheral gate 40, wherein the third isolation layer 52 is spaced apart from the fourth isolation layer 53, to form the second air gap 51 between the third isolation layer 52 and the fourth isolation layer 53; that is, the gate isolator 50 forms an insulation structure of an isolation layer-an air layer-an isolation layer, so as to improve an insulation effect.

It is to be noted that, a height of the second air gap 51, a height of the third isolation layer 52 and a height of the fourth isolation layer 53 are all equal. The height herein is a height in a second direction. The second direction is perpendicular to the first direction, that is, perpendicular to the substrate 10.

In some embodiments, the third isolation layer 52 and the fourth isolation layer 53 may be identical material layers.

In some embodiments, the third isolation layer 52 and the fourth isolation layer 53 may be different material layers.

In some embodiments, the first isolation layer 32 and the third isolation layer 52 are identical material layers. The second isolation layer 33 and the fourth isolation layer 53 are identical material layers.

In some embodiments, as shown in FIG. 20, the semiconductor structure further includes: a sealing layer 90. The sealing layer 90 is arranged above the first air gap 31 and the second air gap 51, to seal the first air gap 31 and the second air gap 51.

In some embodiments, as shown in FIG. 20, the bitline 20 includes the bitline contact portion 21, the bitline metal portion 22 and the bitline insulation portion 23, the bitline contact portion 21 is connected to the plug 60, the bitline metal portion 22 is located on the bitline contact portion 21, and the bitline insulation portion 23 is located on the bitline metal portion 22.

In some embodiments, as shown in FIG. 20, the peripheral gate 40 includes the peripheral gate contact portion 41, the peripheral gate metal portion 42 and the peripheral gate insulation portion 43, the peripheral gate contact portion 41 is located on the substrate 10, the peripheral gate metal portion 42 is located on the peripheral gate contact portion 41, and the peripheral gate insulation portion 43 is located on the peripheral gate metal portion 42.

In some embodiments, the bitline contact portion 21 and the peripheral gate contact portion 41 are made of a same material, the bitline metal portion 22 and the peripheral gate metal portion 42 are made of a same material, and the bitline insulation portion 23 and the peripheral gate insulation portion 43 are made of a same material.

In some embodiments, the semiconductor structure may be obtained with the above semiconductor structure manufacturing method.

It is to be noted that, materials of various structural layers included in the semiconductor structure may be obtained with reference to the materials given in the semiconductor structure manufacturing method, which are not described in detail herein.

Other implementation solutions of the present disclosure will be apparent to those skilled in the art from consideration of the specification and practice disclosed herein. The present disclosure is intended to cover any variations, uses, or adaptations of the present disclosure following the general principles of the present disclosure and including common knowledge or common technical means in the art not disclosed in the present disclosure. It is intended that the specification and embodiments be considered as exemplary only, with a true scope and spirit of the present disclosure being indicated by the appended claims.

It should be understood that the present disclosure is not limited to the exact construction that has been described above and illustrated in the accompanying drawings and that various modifications and changes can be made without departing from the scope thereof. The scope of the present disclosure is limited only by the appended claims.

What is claimed is:

1. A semiconductor structure, comprising:
a substrate, a plurality of active regions being formed in the substrate;
a bitline, the bitline being located on the substrate and connected to the active region;
a bitline isolator, the bitline isolator being located on the substrate and covering a sidewall of the bitline, the bitline isolator comprising a first air gap;
a peripheral gate, the peripheral gate being located on the substrate; and
a gate isolator, the gate isolator being located on the substrate and covering a sidewall of the peripheral gate, the gate isolator comprising a second air gap.

2. The semiconductor structure according to claim 1, wherein the first air gap and the second air gap are synchronously formed.

3. The semiconductor structure according to claim 1, wherein the bitline isolator further comprises:
a first isolation layer, the first isolation layer being located on the substrate; and
a second isolation layer, the second isolation layer being located on the substrate and covering the sidewall of the bitline,
wherein the first isolation layer is spaced apart from the second isolation layer, to form the first air gap between the first isolation layer and the second isolation layer.

4. The semiconductor structure according to claim 1, wherein a bottom of the bitline is located in the substrate.

5. The semiconductor structure according to claim 1, wherein the semiconductor structure further comprises:
a plug, the plug being located in the substrate, the bitline being connected to the active region through the plug.

6. The semiconductor structure according to claim 5, wherein a thickness of the bitline in a first direction is less than a thickness of the plug in the first direction, so that the bitline isolator covers a top end of the plug,
wherein the first direction is parallel to the substrate.

7. The semiconductor structure according to claim 6, wherein a total thickness of the bitline and the bitline isolator in the first direction is greater than the thickness of the plug in the first direction.

8. The semiconductor structure according to claim 1, wherein the gate isolator further comprises:
a third isolation layer, the third isolation layer being located on the substrate; and
a fourth isolation layer, the fourth isolation layer being located on the substrate and covering the sidewall of the peripheral gate,
wherein the third isolation layer is spaced apart from the fourth isolation layer, to form the second air gap between the third isolation layer and the fourth isolation layer.

9. A semiconductor structure manufacturing method, comprising:
providing a substrate, the substrate comprising a memory cell region and a peripheral circuit region, a plurality of active regions being formed in the memory cell region;
forming a bitline on the memory cell region, the bitline being connected to the active region;
forming a bitline isolator on the memory cell region, the bitline isolator covering a sidewall of the bitline, the bitline isolator comprising a first air gap;
forming a peripheral gate on the peripheral circuit region; and
forming a gate isolator on the peripheral circuit region, the gate isolator covering a sidewall of the peripheral gate, the gate isolator comprising a second air gap.

10. The semiconductor structure manufacturing method according to claim 9, wherein the first air gap and the second air gap are synchronously formed by a same process.

11. The semiconductor structure manufacturing method according to claim 10, wherein the step of forming the first air gap and the second air gap comprises:
forming a first insulator on the substrate;
forming a first opening and a second opening on the first insulator, a bottom of the first opening being located in the memory cell region, a bottom of the second opening being located in the peripheral circuit region;
forming a first isolation layer and a third isolation layer on sidewalls of the first opening and the second opening respectively;
forming a first insulation layer and a second insulation layer on sidewalls of the first isolation layer and the third isolation layer respectively;
forming a second isolation layer and a fourth isolation layer on sidewalls of the first insulation layer and the second insulation layer respectively;
forming the bitline and the peripheral gate in the second isolation layer and the fourth isolation layer respectively; and
removing the first insulation layer and the second insulation layer, an air gap between the first isolation layer and the second isolation layer serving as the first air gap, an air gap between the third isolation layer and the fourth isolation layer serving as the second air gap,
wherein the first isolation layer, the second isolation layer and the first air gap serve as the bitline isolator, and the third isolation layer, the fourth isolation layer and the second air gap serve as the gate isolator.

12. The semiconductor structure manufacturing method according to claim 11, wherein a first semiconductor layer is formed in the substrate, and the step of forming the first opening and the second opening comprises:
forming a first mask layer on the first insulator, the first mask layer exposing a first region corresponding to the first opening and a second region corresponding to the second opening; and
forming the first opening in the first region and the second opening in the second region by an etching process,
wherein the bottom of the first opening is located in the substrate so that a part of the first semiconductor layer is etched, a remaining part of the first semiconductor layer serves as a plug connecting the active region and the bitline, and the bottom of the second opening is located on an upper surface of the substrate.

13. The semiconductor structure manufacturing method according to claim 11, wherein a first isolation material layer is formed on the first insulator, and the first isolation layer and the third isolation layer are formed by etching a part of the first isolation material layer; or a first insulation material layer is formed on the first insulator, and the first insulation layer and the second insulation layer are formed by etching a part of the first insulation material layer; or
a second isolation material layer is formed on the first insulator, and the second isolation layer and the fourth isolation layer are formed by etching a part of the second isolation material layer.

14. The semiconductor structure manufacturing method according to claim 11, wherein the first insulator comprises an oxide layer and a nitride layer, the oxide layer is formed on the substrate, the nitride layer is formed on the oxide layer, and the bitline and the peripheral gate are formed after all material layers on an upper surface of the oxide layer are removed,
wherein the oxide layer, the first insulation layer and the second insulation layer are identical material layers to be simultaneously removed by etching.

15. The semiconductor structure manufacturing method according to claim 11, wherein the step of forming the bitline and the peripheral gate comprises:
forming a bitline contact portion and a peripheral gate contact portion in the first opening and the second opening respectively;
forming a bitline metal portion and a peripheral gate metal portion on the bitline contact portion and the peripheral gate contact portion respectively; and
forming a bitline insulation portion and a peripheral gate insulation portion on the bitline metal portion and the peripheral gate metal portion respectively,
wherein the bitline contact portion, the bitline metal portion and the bitline insulation portion serve as the bitline, and the peripheral gate contact portion, the peripheral gate metal portion and the peripheral gate insulation portion serve as the peripheral gate.

16. The semiconductor structure manufacturing method according to claim 15, wherein a second semiconductor material layer is formed on the first insulator, and the bitline contact portion and the peripheral gate contact portion are formed by etching a part of the second semiconductor material layer; or
a metal conductive material layer is formed on the first insulator, and the bitline metal portion and the peripheral gate metal portion are formed by etching a part of the metal conductive material layer; or
a second insulation material layer is formed on the first insulator, and the bitline insulation portion and the peripheral gate insulation portion are formed by etching a part of the second insulation material layer.

17. The semiconductor structure manufacturing method according to claim 11, wherein the semiconductor structure manufacturing method further comprises:
forming a sealing layer on the first air gap and the second air gap.

18. The semiconductor structure according to claim 2, wherein the gate isolator further comprises:
a third isolation layer, the third isolation layer being located on the substrate; and
a fourth isolation layer, the fourth isolation layer being located on the substrate and covering the sidewall of the peripheral gate,
wherein the third isolation layer is spaced apart from the fourth isolation layer, to form the second air gap between the third isolation layer and the fourth isolation layer.

19. The semiconductor structure according to claim 3, wherein the gate isolator further comprises:
a third isolation layer, the third isolation layer being located on the substrate; and
a fourth isolation layer, the fourth isolation layer being located on the substrate and covering the sidewall of the peripheral gate,
wherein the third isolation layer is spaced apart from the fourth isolation layer, to form the second air gap between the third isolation layer and the fourth isolation layer.

20. The semiconductor structure according to claim 4, wherein the gate isolator further comprises:
a third isolation layer, the third isolation layer being located on the substrate; and
a fourth isolation layer, the fourth isolation layer being located on the substrate and covering the sidewall of the peripheral gate,
wherein the third isolation layer is spaced apart from the fourth isolation layer, to form the second air gap between the third isolation layer and the fourth isolation layer.
